(19) United States
(12) Patent Application Publication
(10) Pub. No.: US 2010/0269893 A1
(43) Pub. Date: Oct. 28, 2010

(54) METAL PASTES AND USE THEREOF IN THE PRODUCTION OF POSITIVE ELECTRODES ON P-TYPE SILICON SURFACES

(75) Inventors: Alistair Graeme Prince, Bedminster (GB); Richard John Sheffield Young, Somerset (GB); Giovanna Laudisio, Bristol (GB); Gary Coultart, Bristol (GB)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, WILMINGTON, DE (US)

(21) Appl. No.: 12/766,004

(22) Filed: Apr. 23, 2010

Related U.S. Application Data
(60) Provisional application No. 61/171,859, filed on Apr. 23, 2009.

(51) Int. Cl. H01L 31/042; H01L 21/283; H01L 29/40

(52) U.S. Cl. 136/252; 438/660; 257/734; 252/513; 252/514; 252/512; 257/E21.159; 257/E29.111

(57) ABSTRACT

Metal pastes comprising (a) at least one electrically conductive metal powder selected from the group consisting of silver, copper, and nickel, (b) at least one p-type silicon alloy powder, and (c) an organic vehicle, wherein the p-type silicon alloy is selected from the group consisting of alloys comprising silicon and boron, alloys comprising silicon and aluminum and alloys comprising silicon, boron and aluminum.

### FIELD OF THE INVENTION

The present invention is directed to metal pastes and their use in the production of positive electrodes on p-type (p-doped) silicon surfaces, in particular, in the production of positive electrodes on p-type emitters of silicon solar cells having an n-type (n-doped) silicon base.

### TECHNICAL BACKGROUND OF THE INVENTION

It is well known that radiation of an appropriate wavelength falling on a p-n junction of a semiconductor body serves as a source of external energy to generate electron-hole pairs in that body. The potential difference that exists at a p-n junction, causes holes and electrons to move across the junction in opposite directions, thereby giving rise to flow of an electric current that is capable of delivering power to an external circuit. Most solar cells are in the form of a silicon wafer that has been metallized, i.e., provided with metal contacts which are electrically conductive (metal electrodes).

Most electric power-generating solar cells currently used are silicon solar cells. Electrodes in particular are made by using a method such as screen printing from metal pastes.

A conventional solar cell structure consists of a p-type silicon base with a front n-type silicon surface (front n-type emitter), a negative electrode that is deposited on the front-side (illuminated side, illuminated surface) of the cell and a positive electrode on the back-side.

Alternatively, a reverse solar cell structure with an n-type silicon base is also known. Such cells have a front p-type silicon surface (front p-type emitter) with a positive electrode on the front-side and a negative electrode to contact the back-side of the cell.

Other recent solar cell design concepts also include n-type silicon bases, wherein heterojunction p-type emitters are formed locally on the back surface of the solar cells. Here, positive as well as negative electrodes are located on the back-side of the solar cell.

Solar cells with n-type silicon bases (n-type silicon solar cells) can in theory produce absolute efficiency gains of up to 1% compared to solar cells with p-type silicon bases owing to the reduced recombination velocity of electrons in the n-doped silicon.

The production of an n-type silicon solar cell typically starts with the formation of an n-type silicon substrate in the form of a silicon wafer. To this end, an n-doped base is typically formed via thermal diffusion of a phosphorus containing precursor such as POCl₃into the silicon wafer. On the n-type silicon wafer one or more p-type emitters are typically formed via thermal diffusion of a boron containing precursor such as BBr₃. The resulting p-type emitter is either formed over the entire front-side surface of the n-type silicon wafer, or as local heterojunctions on the back surface. The p-n junction is formed where the concentration of the n-type dopant equals the concentration of the p-type dopant.

A layer of TiOₓ, SiOₓ, TiOₓ/SiOₓ, or, in particular, SiNₓ or Si₃N₄ is typically formed on the wafer to a thickness of between 80 and 150 nm by a process, such as, for example, plasma CVD (chemical vapor deposition). Such a layer serves as an ARC (antireflection coating) layer and/or as a passivation layer.

A solar cell structure with an n-type silicon base has one or more positive electrodes (either one on the front-side or one or more positive electrodes on the back-side) and a negative electrode on the back-side. The positive electrode(s) is/are applied by screen printing, drying and firing an electrically conductive metal paste. In addition, a silver back electrode is formed over portions of the back-side as an electrode for interconnecting solar cells. To this end, a back-side silver paste is screen printed (or some other application method) and successively dried on the back-side of the substrate. The back-side silver paste is fired becoming a silver back electrode. Firing is typically carried out in a belt furnace for a period of 1 to 5 minutes with the wafer reaching a peak temperature in the range of 700 to 900° C. The positive and negative electrodes can be fired sequentially or cofired.

In the particular case of a reverse solar cell structure with an n-type silicon base the solar cell has a positive electrode on the front-side (on the front p-type emitter) and a negative electrode on the back-side. The positive electrode is typically in the form of a grid applied by screen printing, drying and firing a front-side electrically conductive metal paste (front-electrode forming electrically conductive metal paste) on the front-side of the cell. The front-side grid electrode is typically screen printed in a so-called H pattern which comprises (i) thin parallel finger lines (collector lines) and (ii) two busbars intersecting the finger lines at right angle. In addition, a silver back electrode is formed over portions of the back-side as an electrode for interconnecting solar cells. To this end, a back-side silver paste is screen printed (or some other application method) and successively dried on the back-side of the substrate. Normally, the back-side silver paste is screen printed onto the n-type silicon wafer's back-side as a grid, for example, an H pattern grid, or as two parallel busbars or as rectangles (tabs) ready for soldering interconnection strings (presoldered copper ribbons). The back-side silver paste is fired becoming a silver back electrode. Firing is typically carried out in a belt furnace for a period of 1 to 5 minutes with the wafer reaching a peak temperature in the range of 700 to 900° C. The front-side grid electrode and the back electrode can be fired sequentially or cofired.

The challenge for solar cell types with an n-type silicon base is the ability for the metallizations to form good ohmic contact with the p-type emitter. Conventional silver pastes as are used for the manufacture of negative front-side electrodes of conventional solar cells with a p-type silicon base are not useful for the manufacture of positive electrodes on the p-type emitters of n-type silicon solar cells; the energy barrier or, in other words, the ohmic contact resistance between such positive electrodes and the p-type emitter surface is too high.

It has been found that the addition of alloys of silicon and certain group 13 elements (type 3 elements) to per se known thick film conductive pastes allows not only for the production of positive electrodes with good ohmic contact with a p-type silicon surface, but also with good solderability, in particular good solder adhesion. Examples of p-type silicon surfaces include the surface of a p-type silicon semiconductor such as, in particular, the one or more p-type emitters of an n-type silicon solar cell.

### SUMMARY OF THE INVENTION

The present invention relates to metal pastes comprising (a) at least one electrically conductive metal powder selected from the group consisting of silver, copper, and nickel, (b) at least one p-type silicon alloy powder, and (c) an organic vehicle, wherein the p-type silicon alloy is selected from the group consisting of alloys comprising silicon and boron, alloys comprising silicon and aluminum and alloys comprising silicon, boron and aluminum.

In the description and the claims the term “p-type silicon alloy” is used. It means a silicon alloy of the p-type, i.e. the proportion of boron and/or aluminum in such silicon alloy is sufficiently high to ensure the silicon alloy has a p-type character.

The metal pastes of the present invention are thick film conductive compositions that can be applied by printing, in particular, screen printing. They comprise at least one electrically conductive metal powder selected from the group consisting of silver, copper and nickel. Silver powder is preferred. The electrically conductive metal or silver powder may be uncoated or at least partially coated with a surfactant. The surfactant may be selected from, but is not limited to, stearic acid, palmitic acid, lauric acid, oleic acid, capric acid, myristic acid and linolic acid and salts thereof, for example, ammonium, sodium or potassium salts.

The average particle size of the electrically conductive metal powder or, in particular, silver powder is in the range of, for example, 0.5 to 10 μm. The total content of the electrically conductive metal powder or, in particular, silver powder in the metal pastes of the present invention is, for example, 50 to 92 wt.-% (weight-%), or, in an embodiment, 65 to 90 wt.-%.

In the description and the claims the term “average particle size” is used. It means the mean particle diameter (d50) determined by means of laser scattering. All statements made in the present description and the claims in relation to average particle sizes relate to average particle sizes of the relevant materials as are present in the metal pastes.

It is possible to replace a small proportion of the electrically conductive metal selected from the group consisting of silver, copper and nickel by one or more other particulate metals. The proportion of such other particulate metal(s) is, for example, 0 to 10 wt. %, based on the total of particulate metals contained in the conductive metal paste. It may in particular be expedient for the conductive metal paste to contain particulate iridium, particulate platinum and/or particulate palladium as particulate metal(s) replacing a small proportion of the electrically conductive metal. The particulate iridium, platinum and/or palladium may be contained in a total proportion of, for example, 0.5 to 5 wt. %, based on the total of particulate metals contained in the conductive metal paste.

The metal pastes of the present invention comprise at least one p-type silicon alloy powder, wherein the p-type silicon alloy is selected from the group consisting of alloys comprising silicon and boron, alloys comprising silicon and aluminum and alloys comprising silicon, boron and aluminum.

The average particle size of the at least one p-type silicon alloy powder is in the range of, for example, 0.5 to <10 μm. The total content of the at least one p-type silicon alloy powder in the metal pastes of the present invention is, for example, 0.5 to 10 wt.-%, or, in an embodiment, 1 to 5 wt.-%, or, in particular 1.5 to 3 wt.-%.

The p-type silicon alloys are selected from the group consisting of alloys comprising silicon and boron, alloys comprising silicon and aluminum and alloys comprising silicon, boron and aluminum. They comprise binary alloys of silicon with boron, binary alloys of silicon with aluminum, ternary alloys of silicon with aluminum and boron, alloys of silicon with boron and other chemical elements than aluminum, alloys of silicon with aluminum and other chemical elements than boron and alloys of silicon with aluminum, boron and other chemical elements than aluminum and boron. It is preferred to use powders of binary alloys of silicon with boron, of binary alloys of silicon with aluminum and/or of ternary alloys of silicon with aluminum and boron as p-type silicon alloy powder. The binary alloys, in particular the binary alloys of silicon with aluminum are particularly preferred as p-type silicon alloy powders.

The silicon content in the p-type silicon alloys is in the range of, for example, 5 to 20 wt.-%. In case of the particularly preferred binary alloys of silicon with aluminum the silicon content is in the range of, for example, 10 to 15 wt.-%. The eutectic aluminum/silicon alloy (AlSi12) is most preferred.

The metal pastes of the present invention may be free of glass frit. However, usually they comprise glass frit, for example, 0.5 to 10 wt.-%, preferably 2 to 5 wt.-% of glass frit as inorganic binder. The average particle size of the glass frit is in the range of, for example, 0.5 to 4 μm.

The preparation of the glass frit is well known and consists, for example, in melting together the constituents of the glass in the form of the oxides of the constituents and pouring such molten composition into water to form the frit. As is well known in the art, heating may be conducted to a peak temperature and for a time such that the melt becomes entirely liquid and homogeneous.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The metal pastes of the present invention comprise an organic vehicle. A wide variety of inert viscous materials can be used as organic vehicle. The organic vehicle may be one in which the particulate constituents (electrically conductive metal powder, p-type silicon alloy powder, optionally present glass frit and other optionally present particulate inorganic components like particulate inorganic oxides) are dispersible with an adequate degree of stability. The properties, in particular, the rheological properties of the organic vehicle may be such that they lend good application properties to the metal pastes, including: stable dispersion of insoluble solids, appropriate viscosity and thixotropy for application, in particular, for screen printing, appropriate wettability of the p-type silicon surface to be printed and of the paste solids, a good drying rate, and good firing properties. The organic vehicle used in the metal pastes of the present invention may be a nonaqueous inert liquid. The organic vehicle may be an organic solvent or an organic solvent mixture; in an embodiment, the organic vehicle may be a solution of organic polymer(s) in organic solvent(s). Use can be made of any of various organic vehicles, which may or may not contain thickeners, stabilizers and/or other common additives. In an embodiment, the polymer used as constituent of the organic vehicle may be ethyl cellulose. Other examples of polymers which may be used alone or in combination include ethylhydroxyethyl cellulose, wood rosin, phenolic resins and poly(meth)acrylates of lower alcohols. Examples of suitable organic solvents comprise ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the metal pastes can be included in the organic vehicle. Various combinations of these and other solvents may be formulated to obtain the viscosity and volatility requirements desired.

The ratio of organic vehicle in the metal pastes of the present invention to the inorganic components (electrically conductive metal powder plus p-type silicon alloy powder plus optionally present glass frit plus optionally present other inorganic additives) is dependent on the method of applying the metal pastes and the kind of organic vehicle used, and it can vary. Usually, the metal pastes of the present invention will contain 58-95 wt.-% of inorganic components and 5-42 wt.-% of organic vehicle.

The metal pastes of the present invention are viscous compositions, which may be prepared by mechanically mixing the electrically conductive metal powder(s), the p-type silicon alloy powder(s) and the optionally present glass frit with the organic vehicle. In an embodiment, the manufacturing method power mixing, a dispersion technique that is equivalent to the traditional roll milling, may be used; roll milling or other mixing technique can also be used.

The metal pastes of the present invention can be used as such or may be diluted, for example, by the addition of additional organic solvent(s); accordingly, the weight percentage of all the other constituents of the metal pastes may be decreased.

The metal pastes of the present invention may be used in the production of positive electrodes on p-type silicon surfaces of silicon semiconductors. N-type silicon solar cells with one or more p-type emitters represent examples of silicon semiconductors having p-type silicon surfaces. Accordingly, the metal pastes of the present invention may in particular be used in the production of positive electrodes on the p-type emitters of n-type silicon solar cells or respectively in the production of such silicon solar cells. Therefore the invention relates also to such production processes, to positive electrodes and to n-type silicon solar cells made by said production processes.

The process for the production of at least one positive electrode may be performed by (i) providing a silicon semiconductor having at least one p-type silicon surface region, (ii) printing, in particular, screen printing and drying a metal paste of the present invention on said at least one p-type silicon surface region to form at least one electrode and (iii) firing the printed and dried metal paste. As a result of the process at least one positive electrode deposited on the at least one p-type silicon surface region of the silicon semiconductor is obtained. The term “at least one p-type silicon surface region” means that the silicon semiconductor's surface is not necessarily entirely a p-type silicon surface; rather, the silicon semiconductor's surface may comprise surface regions that are other than (different from) p-type silicon, for example, even within a specific surface of the silicon semiconductor, for example, within the front or the back surface of a silicon semiconductor wafer, there may be surface regions of p-type silicon and surface regions other than p-type silicon. In step (ii) the metal paste is printed to form at least one electrode; this means, that—in case of a silicon semiconductor having more than one p-type silicon surface regions—the metal paste may be printed on one, several or each of the more than one p-type silicon surface regions, i.e. accordingly, the silicon semiconductor having at least one p-type silicon surface region is provided with one or more positive electrodes.

In a particular embodiment of the process, the silicon semiconductor is an n-type silicon wafer with at least one p-type emitter (n-type silicon solar cell in the form of an n-type silicon wafer with at least one p-type emitter). The at least one p-type emitter represents at least one p-type silicon surface region of a silicon semiconductor. Here, the process for the production of one or more positive electrodes on the one or more p-type emitters of an n-type silicon solar cell comprises the steps: (i) providing an n-type silicon wafer with at least one p-type emitter and optionally having an ARC and/or passivation layer, (ii) printing, in particular, screen printing and drying a metal paste of the present invention on said at least one p-type emitter (typically on each of the p-type emitters) to form at least one electrode and (iii) firing the printed and dried metal paste. As a result of the process at least one positive electrode deposited on the at least one p-type emitter of the n-type silicon wafer is obtained, i.e. accordingly, the n-type silicon solar wafer with at least one p-type emitter is provided with one or more positive electrodes.

In step (i) of the process according to the particular embodiment, an n-type silicon wafer with one or more p-type emitters is provided. The silicon wafer may have an ARC and/or passivation layer. Such silicon wafers are well known to the skilled person; for brevity reasons reference is made to the section “TECHNICAL BACKGROUND OF THE INVENTION”. The silicon wafer may already be provided with the negative back-side metallization, i.e. with a back-side silver paste as described above in the section “TECHNICAL BACKGROUND OF THE INVENTION”. Application of the back-side silver paste may be carried out before or after the positive electrode(s) is/are finished. The back-side silver paste may be individually fired or cofired with the metal paste of the present invention.

In step (ii) of the process according to the particular embodiment a metal paste of the present invention is printed, in particular, screen printed on the one or more p-type emitters of the n-type silicon wafer. After printing the metal paste is dried, for example, for a period of 1 to 100 minutes with the silicon wafer reaching a peak temperature in the range of 100 to 300° C. Drying can be carried out making use of, for example, belt, rotary or stationary driers, in particular, IR (infrared) belt driers.

The firing of step (iii) of the process according to the particular embodiment may be performed, for example, for a period of 1 to 5 minutes with the silicon wafer reaching a peak temperature in the range of 700 to 900° C. The firing can be carried out making use of, for example, single or multi-zone belt furnaces, in particular, multi-zone IR belt furnaces. The firing may happen in an inert gas atmosphere or in the presence of oxygen, for example, in the presence of air. During firing the organic substance including non-volatile organic material and the organic portion not evaporated during the drying may be removed, i.e. burned and/or carbonized, in particular, burned. In case the silicon wafer has an ARC and/or passivation layer, the metal paste of the present invention fires through said layer during firing and makes electrical contact with the p-type silicon emitters, i.e. with the p-type silicon surface.

### EXAMPLES

The Examples cited here relate to metal pastes fired onto solar cells having an n-type silicon base and a p-type emitter. The discussion below describes how a solar cell is formed utilizing a composition of the present invention and how it is tested for its technological properties.

### (1) Manufacture of Solar Cell

A solar cell was produced as follows:
(i) Monocrystalline silicon wafers were screen-printed front and rear with thick-film conductive compositions. The wafer specifications were as follows: 125 mm×125 mm, n-type bulk silicon, 180 μm thick, p-type 60 Ohm/square BBr₃ diffused front-side emitter, POCl₃ diffused back surface field, acid textured, and passivated front and rear with an SiNₓ:SiO₂ dielectric stack.
(ii) A 15 μm thick silver electrode was screen printed onto the phosphorus doped back surface of the cell using PV145 (commercially available silver paste from E.I. Du Pont de Nemours and Company). The boron doped front-side (emitter) surface of the cell was then screen printed with a 15 μm thick deposition of one of the example silver pastes A to E (see Table 1 below). The H type print pattern used to metallize both the front and back of the cell was a grid of 100 μm wide finger lines, of pitch 2.25 mm coupled to a pair of 2 mm wide busbars intersecting the finger lines at right angle. The pastes were dried between prints using an IR belt drier at a peak temperature of 200° C.
(iii) The printed and dried wafers were then fired in a Centrotherm infra-red furnace at a belt speed of 3000 mm/min with zone temperatures defined as zone 1=450° C., zone 2=520° C., zone 3=570° C. and the final zone=925° C. with the wafers reaching a peak temperature of 825° C. Total firing time was 1 minute. After firing, the metallized wafers became functional photovoltaic devices.

The example silver pastes comprised 80 wt.-% silver powder (d50=2.2 μm), 10 to 13 wt.-% organic vehicle (consisting of polymeric organic resins and organic solvents), 7 wt.-% inorganics (particulate metal oxides and lead-containing glass frit powder) and 0 to 3 wt.-% of either aluminum or AlSi₁₂ powder (d50=6 μm), wherein the sum of the wt.-% totals 100 wt.-%.

### (2) Test Procedures

### Contact Resistance

The contact resistance between the fired front-side electrode and the emitter was measured using a Corescan (contact resistance scan) instrument from SunLab BV (Netherlands). The example wafers were mounted in the tester accordingly, and the appropriate wafer dimensions input into the Corescan software. The contact resistance data is reported in Table 1.

### Solder Adhesion Test

For the solder adhesion test both the ribbon and the front-side busbars were wetted with liquid flux and soldered using a manual soldering iron moving along the complete length of the wafer at a constant rate. The soldering iron tip was adjusted to 325° C. There was no pre-drying or pre-heating of the fluxes prior to soldering.

Flux and solder ribbon used in this test were Kester® 952S and 62Sn-36Pb-2Ag (metal alloy consisting of 62 wt.-% tin, 36 wt.-% lead and 2 wt.-% silver) respectively.

Solder adhesion was measured using a Mecmesin adhesion tester by pulling on the solder ribbon at multiple points along the busbar at a speed of 100 mm/s and a pull angle of 90°. The force to peel the ribbon from the busbar was measured in grams.

TABLE 1

| | | | Contact | Solder |
|---|---|---|---|---|
| | wt.-% Al | wt.-% AlSi₁₂ | resistance | adhesion |
| Example | powder | powder | (mΩ · cm²) | (grams) |
| A | 0.0 | 0.0 | 349 | 358 |
| B | 2.0 | 0.0 | 41 | 190 |
| C | 3.0 | 0.0 | 32 | 166 |
| D | 0.0 | 2.0 | 30 | 340 |
| E | 0.0 | 3.0 | 34 | 249 |

### (3) Discussion

Comparative example A (made with undoped silver paste) exhibited very high contact resistance.

Comparative examples B and C (made with Al doped silver pastes) exhibit dramatically improved contact resistance versus comparative example A; however the adhesion of the solder ribbon to the busbar is significantly degraded.

Examples D and E (according to the invention) exhibit dramatically improved contact resistance versus example A and the solder adhesion and solderability fulfills today's industry requirements.

What is claimed is:

1. Metal pastes comprising (a) at least one electrically conductive metal powder selected from the group consisting of silver, copper, and nickel, (b) at least one p-type silicon alloy powder, and (c) an organic vehicle, wherein the p-type silicon alloy is selected from the group consisting of alloys comprising silicon and boron, alloys comprising silicon and aluminum and alloys comprising silicon, boron and aluminum.

2. The metal pastes of claim 1, wherein the total content of the at least one electrically conductive metal powder is 50 to 92 wt.-%.

3. The metal pastes of claim 1, wherein the at least one electrically conductive metal powder is silver powder.

4. The metal pastes of claim 1, wherein the total content of the at least one p-type silicon alloy powder is 0.5 to 10 wt.-%.

5. The metal pastes of claim 1, wherein the p-type silicon alloy is selected from the group consisting of binary alloys of silicon with boron, binary alloys of silicon with aluminum and ternary alloys of silicon with aluminum and boron.

6. The metal pastes of claim 5, wherein the p-type silicon alloy is eutectic aluminum/silicon alloy (AlSi12).

7. The metal pastes of claim 1 containing 58-95 wt.-% of inorganic components and 5-42 wt.-% of organic vehicle.

8. The metal pastes of claim 1 comprising 0.5 to 10 wt.-% of glass frit.

9. A process for the production of at least one electrode comprising the steps:
(i) providing a silicon semiconductor having at least one p-type silicon surface region,
(ii) printing and drying a metal paste of claim 1 on said at least one p-type silicon surface region to form at least one electrode, and
(iii) firing the printed and dried metal paste.

10. The process of claim 9, wherein the printing in step (ii) is screen printing.

11. The process of claim 9, wherein the silicon semiconductor having at least one p-type silicon surface region is an n-type silicon wafer with at least one p-type emitter.

12. The process of claim 11, wherein the printing in step (ii) is screen printing.

13. An electrode produced according to the process of claim 9.

14. A silicon semiconductor having at least one p-type silicon surface region, wherein the silicon semiconductor is provided with at least one electrode produced according to the process of claim 9.

15. An n-type silicon solar cell comprising an n-type silicon wafer with at least one p-type-emitter, wherein the n-type silicon wafer with at least one p-type-emitter is provided with at least one electrode produced according to the process of claim 11.
